(19) United States
(12) Patent Application Publication
(10) Pub. No.: US 2026/0182171 A1
(43) Pub. Date: Jun. 25, 2026

(54) DISPLAY APPARATUS

(71) Applicant: LG Display Co., Ltd., Seoul (KR)

(72) Inventors: Kyu-Hwang LEE, Paju-si (KR); Jungho BANG, Paju-si (KR); Dongkyu LEE, Goyang-si (KR); Munchan KANG, Goyang-si (KR)

(73) Assignee: LG Display Co., Ltd., Seoul (KR)

(21) Appl. No.: 19/193,136

(22) Filed: Apr. 29, 2025

(30) Foreign Application Priority Data
Dec. 23, 2024 (KR) 10-2024-0194628

(51) Int. Cl. H10K 59/127; H10K 59/131; H10K 59/80

(52) U.S. Cl. CPC H10K 59/1275; H10K 59/131; H10K 59/8052

(57) ABSTRACT

A display apparatus according to this specification includes a substrate including a display area and a non-display area outside the display area, a plurality of light-emitting elements arranged in the display area, a plurality of bonding pads arranged in the non-display area of the substrate, a pad insulating structure disposed on the plurality of bonding pads, a pad hole penetrating the pad insulating structure to expose a portion of the surface of the plurality of bonding pads, a driver circuit chip with a plurality of chip pads arranged spaced apart from the bonding pads, and a plurality of conductive structures disposed between the bonding pads and the chip pads, wherein the conductive structures connect to the bonding pads through the pad hole.

### CROSS REFERENCE TO RELATED APPLICATION

This application claims priority from Korean Patent Application No. 10-2024-0194628 filed on Dec. 23, 2024, in the Korean Intellectual Property Office, and all the benefits accruing therefrom under 35 U.S.C. 119, the contents of which in its entirety are herein incorporated by reference.

### BACKGROUND OF THE

### Technical Field

This specification relates to a display apparatus.

### Description of the Related Art

The display device is applied to various electronic devices such as televisions (TVs), smartphones, laptops, and tablets. To this end, research is ongoing to develop thinner, lighter, and lower-power display devices.

Examples of display devices include liquid crystal display (LCD), field emission display (FED), and organic light-emitting display (OLED) apparatuses.

A display device includes a display panel with a plurality of sub-pixels and a driving unit for driving the display panel. The driving unit may include a scan driver for supplying a scan signal (or gate signal) to the display panel and a data driver for supplying a data signal to the display panel.

The display device may include a display panel where a plurality of pixels is arranged and various electronic components for driving the display panel.

### BRIEF SUMMARY

The method of bonding a driver circuit chip to a display panel may involve different technologies depending on the type of substrate on which the driver circuit chip is mounted. For example, it may include chip on glass (COG), chip on film (COF), or chip on plastic (COP) methods.

Recently, chip on plastic (COP) technology, which involves directly mounting the driver circuit chip on the plastic substrate of the display panel, has been used.

To electrically connect the driver circuit chip and the display panel, a conductive film with multiple conductive balls (or particles) dispersed in an insulating material may be used. For example, the conductive film can be placed between the display panel and the driver circuit chip and bonded through thermal compression. In this case, the conductive balls in the conductive film contact both the display panel and the driver circuit chip, enabling electrical connection between the display panel and the driver circuit chip.

During the process of mounting the driver circuit chip on the pad area of the display panel, pressure may be applied to the plastic substrate of the display panel. Due to the pressure applied to the plastic substrate, the plastic substrate in the pad area of the display panel may deform, or cracks may occur in the pads arranged in the pad area. Additionally, when the conductive balls in the conductive film are unevenly distributed within the insulating material, defects in electrical connection, such as poor connection due to misalignment of the conductive balls, short-circuit defects, or open-circuit defects, may occur.

Accordingly, the inventors of this specification, through various experiments, have invented a display apparatus capable of stably implementing electrical connection between the display panel and the driver circuit chip.

Various embodiments of a display apparatus according to the disclosed specification improve the electrical and mechanical connection between a driver circuit chip and a display panel by reducing or eliminating the use of conductive balls in conventional anisotropic conductive film (ACF) bonding. Instead, a conductive structure composed of solder particles (e.g., tin, indium, or bismuth) dispersed in a non-conductive filler is used. Upon application of specific temperature and pressure conditions, the solder particles self-assemble and grow through intermetallic compound formation with a chip pad (e.g., copper) and a bonding pad that includes a pad pattern formed of an Ag—Mg alloy. The bonding pad also includes a pad capping portion (e.g., LiF), which serves as an etch stop layer during pad hole formation.

To enhance adhesion and contact reliability, in some embodiments, the pad pattern includes recessed grooves formed by removing metal oxide particles (e.g., MgO), thereby increasing surface roughness and the concentration of silver. The conductive structure fills a pad hole having both vertical and horizontal portions, anchors into the recessed grooves, and reduces contact resistance. This configuration enables fine-pitch pad design, reduces crack and short/open-circuit defects, and lowers manufacturing energy and greenhouse gas emissions, thereby improving reliability in flexible substrate applications.

Various embodiments of this specification provide a display apparatus capable of preventing electrical connection defects between the display panel and the driver circuit chip.

Various embodiments of this specification provide a display apparatus capable of preventing defects caused by misalignment and cracks during the process of mounting the driver circuit chip on the pad area of the display panel.

Various embodiments of this specification provide a display apparatus capable of reducing defect rates, production energy, and greenhouse gas emissions by preventing connection defects in pads with fine pitch.

The technical benefits of the embodiments in this specification are not limited to the foregoing, and other benefits and advantages of the present disclosure not mentioned can be understood through the following description and will be more clearly understood through the embodiments of this specification. Moreover, it will be readily apparent that the objects and advantages of this specification can be realized by the means and combinations thereof set forth in the claims.

A display apparatus according to an embodiment of this specification may include a substrate including a display area and a non-display area outside the display area, a plurality of light-emitting elements arranged in the display area, a plurality of bonding pads arranged in the non-display area of the substrate, a pad insulating structure disposed on the plurality of bonding pads, a pad hole penetrating the pad insulating structure to expose a portion of the surface of the plurality of bonding pads, a driver circuit chip with a plurality of chip pads arranged spaced apart from the bonding pads, and a plurality of conductive structures disposed between the bonding pads and the chip pads, wherein the conductive structures may connect to the bonding pads through the pad hole.

A display apparatus according to another embodiment of this specification may include a substrate including a display area and a non-display area outside the display area, a plurality of bonding pads arranged in the non-display area of the substrate, a pad insulating structure disposed on the plurality of bonding pads, a pad hole penetrating the pad insulating structure to expose a portion of the surface of the plurality of bonding pads, a driver circuit chip with a plurality of chip pads arranged spaced apart from the bonding pads, and a plurality of conductive structures disposed between the bonding pads and the chip pads, wherein a plurality of recessed grooves are disposed on the upper surface of the bonding pad, and the conductive structure may fill the plurality of recessed grooves of the bonding pad through the pad hole.

### BRIEF DESCRIPTION OF THE SEVERAL VIEWS OF THE DRAWINGS

FIG. 1 is an exploded perspective view of a display apparatus according to embodiments of this specification;

FIG. 2 is a plan view of a display panel according to embodiments of this specification;

FIG. 3 is a diagram according to an embodiment of this specification;

FIG. 4 is a cross-sectional view along line II-II′ of FIG. 2;

FIG. 5 is an enlarged cross-sectional view of region III of FIG. 3;

FIGS. 6 and 7 are diagrams illustrating a bonding method between a substrate and a driver circuit chip package;

FIGS. 8 to 14 are diagrams illustrating a method of manufacturing a pad portion according to an embodiment of this specification;

FIG. 15 is a diagram illustrating a pad portion according to another embodiment of this specification;

FIGS. 16 to 21 are diagrams illustrating a method of manufacturing a pad portion according to another embodiment of this specification; and

FIGS. 22 and 23 are diagrams illustrating the filling state of a conductive structure.

### DETAILED DESCRIPTION

Advantages and features disclosed in this specification and methods of accomplishing the same may be understood more readily by reference to the detailed description of embodiments that will be made hereinafter with reference to the accompanying drawings. This specification is not limited to the embodiments described herein but may be embodied in various forms, and the embodiments are provided to ensure a complete disclosure of the disclosure and to fully convey the scope of the disclosure to those skilled in the art in the relevant technical field.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the specification, the same reference numerals refer to the same components. In addition, detailed descriptions of well-known technologies may be omitted in the specification to avoid obscuring the subject matter of the specification. When terms such as “comprises,” “has,” “includes,” or “is made up of” are used in this specification, it should be understood that unless “only” is specifically used, additional elements or steps can be included. Unless otherwise explicitly stated, when a component is expressed in the singular form, it is intended to encompass the plural form as well.

As used herein, the term “filled” should not be narrowly interpreted to mean that A is filled exclusively with B to the exclusion of all other materials. Rather, the phrase “filled with,” as used herein, is intended to encompass a broad range of conditions, including but not limited to: “partially filled with,” “substantially filled with,” “completely filled with,” or “exclusively filled with.”

In interpreting the components, it is construed to include a margin of error even in the absence of explicit description.

When describing positional relationships, expressions such as “on,” “above,” “below,” or “beside” may indicate the positional relationship between two parts, and unless “immediately” or “directly” is used, one or more other parts may be located between the two parts.

When describing temporal relationships, expressions such as “after,” “following,” “next,” or “before” may indicate a sequence of events, and unless “immediately” or “directly” is used, non-continuous cases may also be included.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “in contact” and “coupled” should be interpreted in the same manner.

Terms like “first,” “second,” etc., are used to describe various components, but these components are not limited by these terms. These terms are merely used for distinguishing one component from the other components. Therefore, the first component mentioned hereinafter may be the second component in the technical sense of this specification.

The various features of the embodiments of the disclosure can combined or assembled together, either partially or entirely, in a technically diverse manner, and each embodiment can be independently implemented or in conjunction with related embodiments.

Hereinafter, a display apparatus according to each embodiment of the present disclosure will be described with reference to the accompanying drawings.

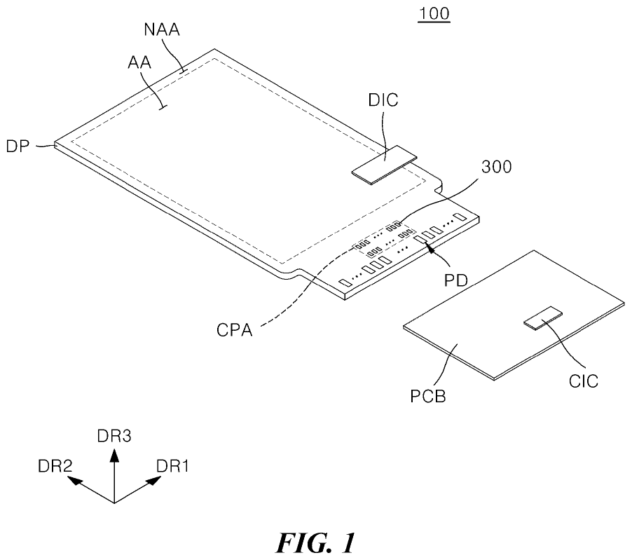

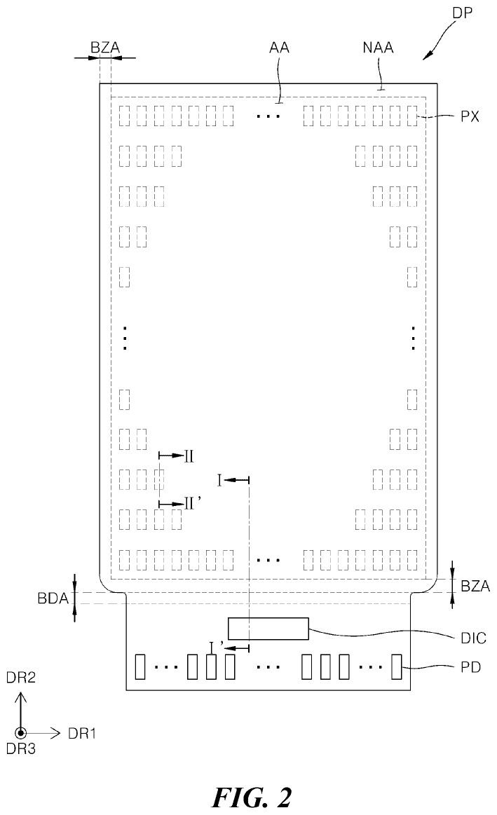

FIG. 1 is an exploded perspective view of a display apparatus according to embodiments of this specification. FIG. 2 is a plan view of a display panel according to embodiments of this specification.

Referring to FIGS. 1 and 2, the display apparatus 100 may include a display panel DP, a driver circuit chip package DIC, a printed circuit board PCB, and a control circuit chip CIC.

The display panel DP may include a plurality of sub-pixels PX, a plurality of chip pads CPD, and a plurality of connection pads PD. The plurality of sub-pixels PX may be arranged in the display area AA of the display panel DP, while the plurality of chip pads CPD and the plurality of connection pads PD may be arranged in the non-display area NAA.

The display area AA may be the area where images are displayed. The non-display area NAA may be the area where images are not displayed. The non-display area NAA may be located in the peripheral area (or border area) of the display panel 100, but is not limited thereto. For example, the area other than the emissive area where light is emitted externally on the display area AA may be referred to as the non-display area NAA. The non-display area NAA may define the bezel area BZA of the display apparatus 100. The bezel area BZA may surround the outer side of the display area AA.

A plurality of sub-pixels PX may be arranged in the display area AA. Each sub-pixel PX may include a light-emitting element and circuit elements for driving the light-emitting element. For example, the circuit elements may include transistors and capacitors. A plurality of sub-pixels PX may display an image in the display area AA. The plurality of sub-pixels PX may be arranged in the display area AA, spaced apart from each other in a first direction DR1 and a second direction DR2 intersecting the first direction DR1.

The non-display area NAA may include various wiring and circuits for driving the plurality of sub-pixels PX in the display area AA. For example, the non-display area NAA may include driving circuits such as a gate driving circuit and a data driving circuit. The non-display area NAA may include various drivers for driving the display area AA. For example, the drivers may include a gate driver and a data driver, but are not limited thereto.

The non-display area NAA may include a bonding pad area CPA where a plurality of bonding pads 300 are arranged. A driver circuit chip package DIC may be mounted in the bonding pad area CPA. The driver circuit chip package DIC may be arranged to overlap the plurality of bonding pads 300 in the vertical direction. The chip pads of the driver circuit chip package DIC may be electrically connected to the bonding pads 300 of the display panel DP.

The printed circuit board PCB may be electrically connected to the plurality of connection pads PD of the display panel DP. The control circuit chip CIC may be mounted on the printed circuit board PCB. The printed circuit board PCB may be a flexible printed circuit board. The control circuit chip CIC may control the driver circuit chip package DIC and the gate driver.

The bending area BDA of the display panel DP may be bent, allowing the printed circuit board PCB and the driver circuit chip package DIC to be positioned below the display area AA of the display panel DP.

The bending area BDA may be an area located between the display panel DP and the driver circuit chip package DIC. For example, the bending area BDA may be a portion of the non-display area NAA of the display panel DP where the driver circuit chip package DIC is not mounted.

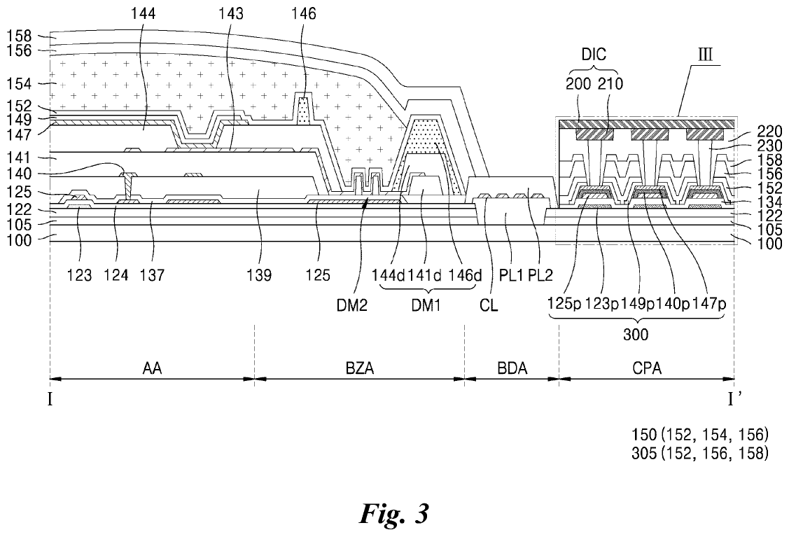

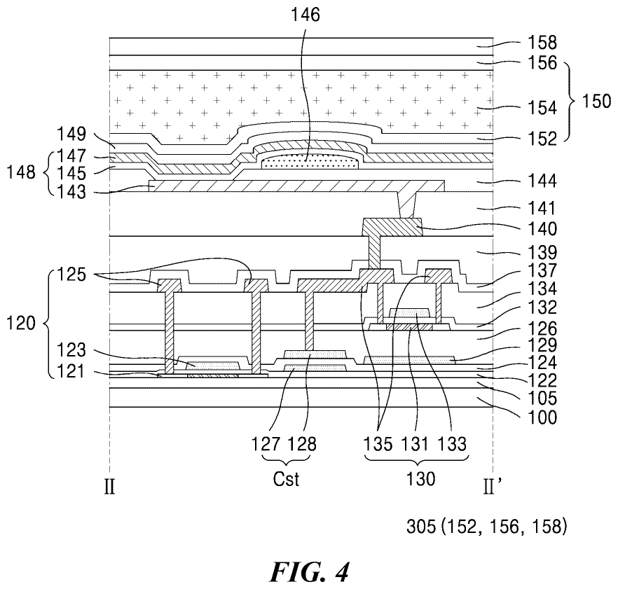

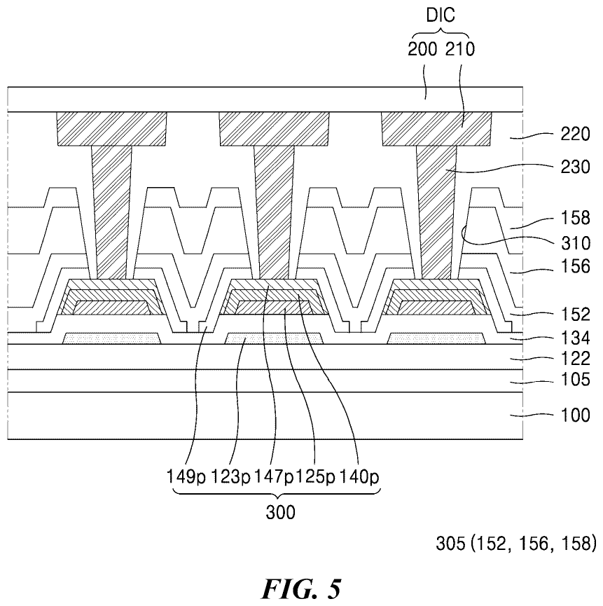

FIG. 3 is a diagram according to an embodiment of this specification. FIG. 4 is a cross-sectional view along line II-II′ of FIG. 2. FIG. 5 is an enlarged cross-sectional view of region III of FIG. 3. FIG. 3 is a cross-sectional view along line I-I′ of FIG. 1. FIG. 4 schematically illustrates one sub-pixel of the display apparatus. For convenience of explanation, this specification describes the configuration of a single sub-pixel, but is not limited thereto. FIG. 5 describes a structure in which a plurality of bonding pads arranged in the chip pad area are combined with the chip pads of the driver circuit chip package.

Referring to FIGS. 3 to 5, the display panel DP (FIG. 2) may include a plurality of transistors 120 and 130, a capacitor Cst, and a light-emitting element 148 disposed on a substrate 100. The plurality of transistors 120, 130 may include a first transistor 120 containing a polycrystalline semiconductor material and a second transistor 130 containing an oxide semiconductor material.

One sub-pixel may include a light-emitting element 148 and a pixel driving circuit that applies a driving current to the light-emitting element 148. The pixel driving circuit is disposed on the substrate 100, and the light-emitting element 148 is disposed on the pixel driving circuit. The pixel driving circuit may include a driving transistor, one or more switching transistors, and a capacitor. In one example, the first transistor 120 may be a switching transistor. The second transistor 130 may be a driving transistor, but is not limited thereto.

The substrate 100 may be a glass or flexible plastic substrate. When the substrate 100 is a plastic film, it may include an organic insulating material such as polyimide.

A buffer layer 105 may be disposed on the substrate 100. The buffer layer 105 may block moisture or impurities that could penetrate the substrate 100 from the outside. The buffer layer 105 may be a single layer or multilayer made of inorganic insulating materials such as silicon oxide (SiOx) or silicon nitride (SiNx).

A first transistor 120 may be disposed on the buffer layer 105. The first transistor 120 may include a first active layer 121, a first gate electrode 123 overlapping the channel region of the first active layer 121, and first source/drain electrodes 125 respectively connected to the source/drain regions disposed on both sides of the channel region of the first active layer 121. In one example, the first active layer 121 may include polycrystalline silicon.

The first active layer 121 may be disposed on the buffer layer 105. A first gate insulating layer 122 may be disposed between the first gate electrode 123 and the first active layer 121. The first gate insulating layer 122 may cover the first active layer 121. The first gate insulating layer 122 may be a single layer or multilayer made of inorganic insulating materials such as silicon oxide (SiOx) or silicon nitride (SiNx).

A light-shielding layer of an opaque material overlapping the first active layer 121 may be disposed between the substrate 100 and the buffer layer 105. The light-shielding layer may block light incident on the first active layer 121, thereby ensuring the reliability of the first transistor 120.

The capacitor Cst includes a first capacitor electrode 127 and a second capacitor electrode 128. The first capacitor electrode 127 may be disposed on the first gate insulating layer 122. The first capacitor electrode 127 may be formed of the same material as the first gate electrode 123 of the first transistor 120. The first gate electrode 123 and the first capacitor electrode 127 may be made of a metal material. For example, the first gate electrode 123 and the first capacitor electrode 127 may be a single layer or multilayer made of any one of molybdenum (Mo), aluminum (Al), chromium (Cr), gold (Au), titanium (Ti), nickel (Ni), neodymium (Nd), and copper (Cu), or an alloy thereof, but are not limited thereto.

A first interlayer insulating layer 124 may be disposed on the first gate electrode 123 and the first capacitor electrode 127. The first interlayer insulating layer 124 may be a single layer or multilayer made of inorganic insulating materials such as silicon oxide (SiOx) or silicon nitride (SiNx).

A second capacitor electrode 128 of the capacitor Cst and a light-shielding layer 129 may be disposed on the first interlayer insulating layer 124. The second capacitor electrode 128 may be formed of the same material as the light-shielding layer 129. The second capacitor electrode 128 and the light-shielding layer 129 are made of a metal material. For example, the second capacitor electrode 128 and the light-shielding layer 129 may be a single layer or multilayer made of any one of molybdenum (Mo), aluminum (Al), chromium (Cr), gold (Au), titanium (Ti), nickel (Ni), neodymium (Nd), and copper (Cu), or an alloy thereof, but are not limited thereto.

A second interlayer insulating layer 126 may be disposed on the second capacitor electrode 128 and the light-shielding layer 129. A second transistor 130 may be disposed on the second interlayer insulating layer 126. The second transistor 130 may include a second active layer 131, a second gate electrode 133 overlapping the channel region of the second active layer 131, and second source/drain electrodes 135 respectively connected to the source/drain regions disposed on both sides of the channel region of the second active layer 131.

The second interlayer insulating layer 126 may separate the second active layer 131 from the first active layer 121. The second interlayer insulating layer 126 may be a single layer or multilayer made of inorganic insulating materials such as silicon oxide (SiOx) or silicon nitride (SiNx). The second active layer 131 may be disposed on the second interlayer insulating layer 126. The second active layer 131 may include an oxide semiconductor material. A second gate insulating layer 132 may be disposed between the second gate electrode 133 and the second active layer 131. The second gate insulating layer 132 may cover the second active layer 131. The second gate insulating layer 132 may be a single layer or multilayer made of inorganic insulating materials such as silicon oxide (SiOx) or silicon nitride (SiNx).

The second gate electrode 133 may include a metal material. For example, the second gate electrode 133 may be a single layer or multilayer made of any one of molybdenum (Mo), aluminum (Al), chromium (Cr), gold (Au), titanium (Ti), nickel (Ni), neodymium (Nd), and copper (Cu), or an alloy thereof, but is not limited thereto.

The light-shielding layer 129 may be disposed to overlap the second active layer 131 in the vertical direction. The light-shielding layer 129 may block light incident on the second active layer 131, thereby ensuring the reliability of the second transistor 130.

A third interlayer insulating layer 134 may be disposed on the second gate electrode 133. The first source/drain electrodes 125 and the second source/drain electrodes 135 may be disposed on the third interlayer insulating layer 134. The first source/drain electrodes 125 may penetrate the third interlayer insulating layer 134, the second gate insulating layer 132, the second interlayer insulating layer 126, the first interlayer insulating layer 124, and the first gate insulating layer 122 to be respectively connected to the source/drain regions of the first active layer 121. The second source/drain electrodes 135 may penetrate the third interlayer insulating layer 134 and the second gate insulating layer 132 to be respectively connected to the source/drain regions of the second active layer 131.

The first source/drain electrodes 125 and the second source/drain electrodes 135 may be formed of the same material in the same process on the third interlayer insulating layer 134. For example, they may be a single layer or multilayer made of any one of molybdenum (Mo), aluminum (Al), chromium (Cr), gold (Au), titanium (Ti), nickel (Ni), neodymium (Nd), and copper (Cu), or an alloy thereof, but are not limited thereto. In one example, the first source/drain electrodes 125 and the second source/drain electrodes 135 may be a stacked structure of titanium/aluminum/titanium (Ti/Al/Ti).

The second source/drain electrodes 135 of the second transistor 130 may penetrate the third interlayer insulating layer 134, the second gate insulating layer 132, and the upper buffer layer 126 to be electrically connected to the second capacitor electrode 128 of the capacitor Cst. However, it is not limited thereto.

A passivation layer 137 may be disposed on the first source/drain electrodes 125, the second source/drain electrodes 135, and the third interlayer insulating layer 134. The passivation layer 137 may include an inorganic insulating material. In one example, the passivation layer 137 may extend from the display area AA to the bezel area BZA, but is not limited thereto.

A first planarization layer 139 may be disposed on the passivation layer 137. The first planarization layer 139 may planarize steps caused by the underlying pixel driving circuit. The first planarization layer 139 may include an organic insulating material such as polyimide or acrylic resin. An intermediate electrode 140 may be disposed on the first planarization layer 139. The intermediate electrode 140 may penetrate the first planarization layer 139 to be connected to the second source/drain electrodes 135 of the second transistor 130. A second planarization layer 141 may be disposed on the intermediate electrode 140 and the first planarization layer 139. The second planarization layer 141 may include an organic insulating material such as polyimide or acrylic resin.

As shown in FIG. 3, the first planarization layer 139 may be disposed to extend to a portion of the bezel area BZA. The second planarization layer 141 may be disposed to cover the sidewall of the first planarization layer 139 in the bezel area BZA.

A light-emitting element 148 may be formed on the second planarization layer 141. The light-emitting element 148 may include a first electrode 143, a second electrode 147, and a light-emitting layer 145 disposed between the first electrode 143 and the second electrode 147.

The light-emitting element 148 may be electrically connected to the pixel driving circuit through the intermediate electrode 140 disposed on the first planarization layer 139. For example, the first electrode 143 of the light-emitting element 148 may be electrically connected to the second source/drain electrodes 135 of the second transistor 130 through the intermediate electrode 140. The first electrode 143 may penetrate the second planarization layer 141 to be connected to the intermediate electrode 140. The intermediate electrode 140 may penetrate the first planarization layer 139 to be connected to the second source/drain electrodes 135.

The intermediate electrode 140 may be a single layer or multilayer made of any one of molybdenum (Mo), aluminum (Al), chromium (Cr), gold (Au), titanium (Ti), nickel (Ni), neodymium (Nd), and copper (Cu), or an alloy thereof, but is not limited thereto. In one example, the intermediate electrode 140 may be a stacked structure of titanium/aluminum/titanium (Ti/Al/Ti).

The first electrode 143 may include a transparent conductive film. The first electrode 143 may include indium tin oxide (ITO) or indium zinc oxide (IZO). The first electrode 143 may also be referred to as an anode electrode or a pixel electrode.

A bank 144 may be disposed on the first electrode 143. The bank 144 may be disposed to cover the edges of the first electrode 143. A portion of the bank 144 may extend to the second planarization layer 141. The upper surface of the first electrode 143 that is exposed without being covered by the bank 144 may serve as the light-emitting area. The bank 144 may be made of an organic insulating material. For example, the bank 144 may include photosensitive polyimide, photoacrylic, or benzocyclobutene (BCB). In one example, the bank 144 may be formed of an opaque material to prevent optical interference between adjacent sub-pixels. In this case, the bank 144 may include a color pigment, organic black, or carbon black.

A spacer 146 may be further disposed on the bank 144. The spacer 146 may be disposed to prevent damage to the bank 144 and the first electrode 143 during the manufacturing process. The spacer 146 may be made of the same material as the bank 144. In this case, it may be formed simultaneously with the bank 144 through a single process, but is not limited thereto. In another example, the spacer 146 may be made of a different material from the bank 144 through a separate process. The spacer 146 may include an organic insulating material. The spacer 146 may include photosensitive polyimide, photoacrylic, or benzocyclobutene (BCB).

A light-emitting layer 145 may be disposed on the first electrode 143. The light-emitting layer 145 may include a hole transport layer (HTL), an organic emission layer (EML), an electron transport layer (ETL), a hole blocking layer (HBL), a hole injecting layer (HIL), an electron blocking layer (EBL), and an electron injecting layer (EIL).

A second electrode 147 may be disposed on the light-emitting layer 145. The second electrode 147 may be formed across the entire surface of the substrate 100 to be commonly connected to the light-emitting layers 145 formed in all pixels PX. Thus, the second electrode 147 may also be referred to as a cathode electrode or a common electrode. The second electrode 147 may include a semi-transmissive conductive material. For example, it may be formed of a metal material such as magnesium (Mg), silver (Ag), or an alloy of silver (Ag) and magnesium (Mg) (Ag—Mg). In one example, the second electrode 147 may include an alloy in which silver (Ag) and magnesium (Mg) are added in a ratio of 12:1, with the proportion of silver (Ag) being relatively higher than that of magnesium (Mg) in the overall alloy.

A capping layer 149 may be disposed on the second electrode 147. The capping layer 149 may include a fluorine-based protective layer. For example, it may include lithium fluoride (LiF). The fluorine-based protective layer, being highly resistant to dry etching, may serve as an etch stop layer during the dry etching process. This will be described in detail with reference to FIG. 5.

As shown in FIG. 3, the bezel area BZA may include a first dam DM1 and a second dam DM2. The first dam DM1 may be composed of a stacked structure in which a first layer 141d, a second layer 144d, and a third layer 146d are laminated. For example, the first layer 141d of the first dam DM1 may be formed of the same material as the second planarization layer 141 in the same process. The second layer 144d may be formed of the same material as the bank 144 in the same process. The third layer 146d may be formed of the same material as the spacer 146 in the same process. A second dam DM2 may be disposed between the first dam DM1 and the display area AA. The second dam DM2 may be formed of the same material as the second planarization layer 141 in the same process. In one example, a portion of the first electrode 143 may extend from the display area AA to the bezel area BZA. The portion of the first electrode 143 extending to the bezel area BZA may cover a part of the upper surface of the first layer 141d of the first dam DM1.

The bending area BDA, disposed between the bezel area BZA and the bonding pad area CPA, may have the buffer layer 105, the first gate insulating layer 122, and the first interlayer insulating layer 124 removed, exposing the surface of the substrate 100. A first protective layer PL1 may be disposed on the exposed surface of the substrate 100. The first protective layer PL1 may overlap the bending area BDA and extend to a portion of the bezel area BZA and a portion of the bonding pad area CPA. A plurality of connection wirings CL and a second protective layer PL2 on the connection wirings may be disposed on the first protective layer PL1. The connection wirings CL may transmit signals provided from the driver circuit chip package DIC or the printed circuit board to the display area AA. The second protective layer PL2 may reduce stress applied to the connection wirings CL during bending. In one example, the first protective layer PL1 and the second protective layer PL2 may include an organic insulating material.

An encapsulation part 150 may be disposed on the capping layer 149. The encapsulation part 150 may prevent moisture or foreign substances from penetrating the light-emitting element 148. The encapsulation part 150 may include a first encapsulation layer 152, a second encapsulation layer 154, and a third encapsulation layer 156. The encapsulation part 150 may be made of an inorganic material, an organic material, or a mixture of inorganic and organic materials, and may be configured as a single layer or multilayer. For example, the first encapsulation layer 152 and the third encapsulation layer 156 may be formed of inorganic insulating materials such as silicon oxide (SiOx) or silicon nitride (SiNx). For example, the second encapsulation layer 154 may be formed of organic insulating materials such as acrylic resin, epoxy resin, phenolic resin, polyamide resin, or polyimide resin.

The first encapsulation layer 152 may extend from the display area AA to the bezel area BZA. The second encapsulation layer 154 may be disposed at a position lower than the first dam DM1. The third encapsulation layer 156 may be disposed from the display area AA to the bezel area BZA.

A touch insulating layer 158 may be disposed on the third encapsulation layer 156. Although not shown in the drawings, a touch array part, including a plurality of touch electrodes for touch operation, touch wirings electrically connecting the plurality of touch electrodes, and a touch protective layer protecting the touch electrodes, may be disposed on the touch insulating layer 158. The touch insulating layer 158 may extend from the display area AA to the bezel area BZA. In one example, the touch insulating layer 158 may extend to a portion of the bending area BDA, but is not limited thereto.

Referring to FIGS. 3 and 5, a plurality of bonding pads 300 may be disposed on the substrate 100. A driver circuit chip package DIC may be disposed to face the substrate 100. The driver circuit chip package DIC may include a driver circuit chip 200 and a plurality of chip pads 210 disposed on the back surface of the driver circuit chip 200. The driver circuit chip package DIC and the substrate 100 may be electrically connected through conductive structures 230 respectively disposed between the plurality of chip pads 210 and the plurality of bonding pads 300.

One bonding pad 300 may include a first pad pattern 123p, a second pad pattern 125p, a third pad pattern 140p, a fourth pad pattern 147p, and a pad capping portion 149p. The bonding pad 300 may be covered by insulating layers stacked in the vertical direction. For example, a third interlayer insulating layer 134 may be disposed between the first pad pattern 123p and the second pad pattern 125p. A multilayer pad insulating structure 305 may be disposed on the pad capping portion 149p. The pad insulating structure 305 may include a first encapsulation layer 152, a third encapsulation layer 156, and a touch insulating layer 158. The third encapsulation layer 156 and the touch insulating layer 158 may be sequentially disposed on the first encapsulation layer 152.

The pad insulating structure 305 may include a pad hole 310. The pad hole 310 may penetrate the pad insulating structure 305 to expose a portion of the surface of the fourth pad pattern 147p.

A conductive structure 230 may be disposed between the chip pad 210 and the bonding pad 300. One surface of the conductive structure 230 may be connected to the chip pad 210, and the other surface may be connected to the fourth pad pattern 147p of the bonding pad 300 exposed by the pad hole 310. The conductive structure 230 may be an alloy including at least one of tin (Sn), indium (In), and bismuth (Bi).

The conductive structure 230 may be an alloy including at least one of tin (Sn), indium (In), and bismuth (Bi). The non-conductive filler 220 may include an organic insulating material. For example, the organic insulating material may include resin or epoxy-based resin, but is not limited thereto.

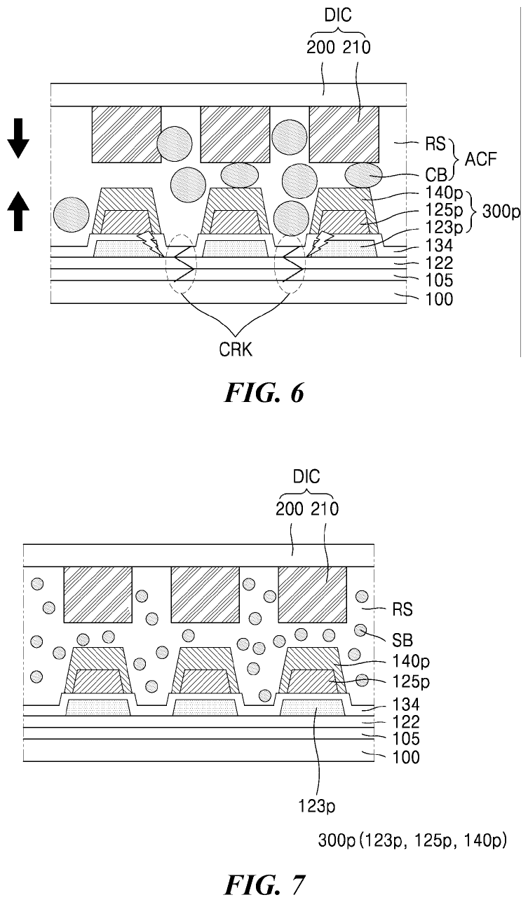

FIGS. 6 and 7 are diagrams illustrating a bonding method between a substrate and a driver circuit chip package.

Referring to FIG. 6, an anisotropic conductive film ACF can be used to electrically connect the driver circuit chip package DIC and the substrate 100 of the display panel. The anisotropic conductive film ACF may be configured with a plurality of conductive balls CB dispersed within an insulating material RS. The anisotropic conductive film ACF can be disposed between the chip pad 210 and the bonding pad 300p and bonded through thermal compression at high pressure. For example, this process can be performed at a pressure greater than 6 MPa and a temperature higher than 250 degrees. As a result, the conductive balls CB can make electrical contact with the chip pad 210 and the third pad pattern 140p of the bonding pad 300p. The bonding pad 300p may include a first pad pattern 123p, a second pad pattern 125p, and a third pad pattern 140p.

However, as shown in FIG. 6, applying a pressure greater than 6 MPa to bring the conductive balls CB into contact with the chip pad 210 and the bonding pad 300p may cause cracks CRK in the insulating layer between adjacent bonding pads 300p. Additionally, the pressure may cause defects such as cracking of the substrate 100, which includes a plastic film. Furthermore, when the plurality of conductive balls CB are not uniformly distributed within the insulating material RS but are clustered in localized areas, short circuits may occur, or when no conductive balls CB are disposed between the chip pad 210 and the bonding pad 300p, defects such as failure of electrical connection may occur. Moreover, misalignment between the chip pad 210 and the bonding pad 300p may reduce the contact area with the conductive balls CB, leading to defects in stable conduction. In particular, when the substrate 100, which includes a plastic film, is cracked, repair is impossible. Consequently, there is an increasing need for methods that eliminate alignment between the chip pad 210 and the bonding pad 300p and for bonding methods that can be performed at lower pressures.

Referring to FIG. 7, there is a method of using solder particles SB instead of conductive balls to electrically connect the chip pad 210 and the bonding pad 300p. To achieve this, an intermetallic compound must be formed between the solder particles SB and the chip pad 210, as well as between the solder particles SB and the third pad pattern 140p located on the outermost surface of the bonding pad 300p. However, solder particles SB containing tin (Sn) do not chemically react with metal materials such as titanium (Ti) and indium tin oxide (ITO) that constitute the third pad pattern 140p. In other words, since no intermetallic compound is formed between the solder particles SB and the third pad pattern 140p, the chip pad 210 and the bonding pad 300 are not electrically connected.

Hereinafter, an embodiment of a conductive structure implemented to electrically connect the chip pad and the bonding pad will be described.

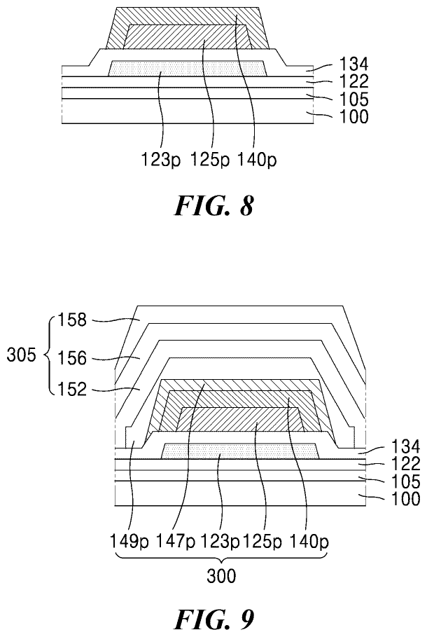

FIGS. 8 to 14 are diagrams illustrating a method of manufacturing a pad portion according to an embodiment of this specification. FIGS. 8 to 14 include the same configuration as FIGS. 3 and 4, so redundant descriptions will be omitted or briefly explained. The same reference numerals may denote the same components.

Referring to FIG. 8, a buffer layer 105 and a first gate insulating layer 122 may be disposed on the substrate 100 in the bonding pad area CPA (see FIG. 3). The buffer layer 105 and the first gate insulating layer 122 may be formed extending from the display area AA.

A first pad pattern 123p, a second pad pattern 125p, and a third pad pattern 140p may be formed on the first gate insulating layer 122. The first pad pattern 123p and the second pad pattern 125p may be disposed spaced apart in the vertical direction. The third pad pattern 140p may cover the upper surface and sidewall surfaces of the second pad pattern 125p. A third insulating layer 134 may be disposed between the first pad pattern 123p and the second pad pattern 125p. The third pad pattern 140p may expose a portion of the surface of the third insulating layer 134.

The first pad pattern 123p may be formed of the same material in the same process as the first gate electrode 123 in the display area AA. For example, the first pad pattern 123p may be a single layer or multilayer made of any one of molybdenum (Mo), aluminum (Al), chromium (Cr), gold (Au), titanium (Ti), nickel (Ni), neodymium (Nd), and copper (Cu), or an alloy thereof, but is not limited thereto.

Each of the second pad pattern 125p and the third pad pattern 140p may be formed of the same material in the same process as the first source/drain electrodes 125 and the second source/drain electrodes 135 in the display area AA, respectively. In one example, the second pad pattern 125p and the third pad pattern 140p may be a stacked structure of titanium/aluminum/titanium (Ti/Al/Ti).

Referring to FIG. 9, a fourth pad pattern 147p may be disposed on the third pad pattern 140p. Accordingly, a bonding pad 300 including the first pad pattern 123p, the second pad pattern 125p, the third pad pattern 140p, the fourth pad pattern 147p, and the pad capping portion 149p can be configured.

The fourth pad pattern 147p may be formed of the same material in the same process as the second electrode 147 in the display area AA. The fourth pad pattern 147p may have a thickness of less than 200k. For example, the fourth pad pattern 147p may be formed of a metal alloy material such as a silver (Ag)-magnesium (Mg) alloy (Ag:Mg). In one example, the fourth pad pattern 147p may include an alloy in which silver (Ag) and magnesium (Mg) are added in a ratio of 12:1. The silver (Ag)-magnesium (Mg) alloy (Ag:Mg) has excellent corrosion resistance to wet etching sources, allowing it to serve as an etch stop layer in a wet etching process.

A pad capping portion 149p may be disposed on the fourth pad pattern 147p. The pad capping portion 149p may be formed of the same material in the same process as the capping layer 149 in the display area AA. For example, the pad capping portion 149p may include lithium fluoride (LiF). In one example, the pad capping portion 149p may be formed with a thickness of 1000 Å to 1500 Å.

A pad insulating structure 305 including multiple insulating layers may be disposed on the pad capping portion 149p. For example, the pad insulating structure 305 may include a first encapsulation layer 152, a third encapsulation layer 156, and a touch insulating layer 158. The first encapsulation layer 152, the third encapsulation layer 156, and the touch insulating layer 158 may each be formed extending from the display area AA.

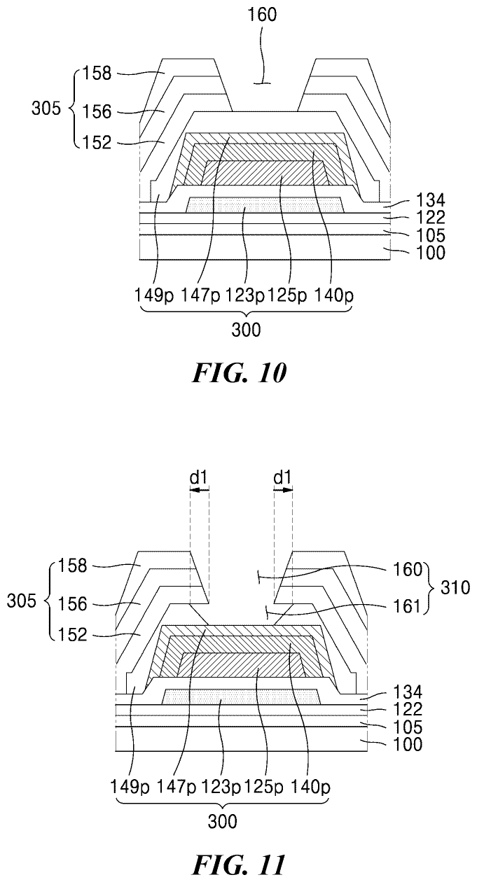

Referring to FIG. 10, a first hole 160 penetrating the pad insulating structure 305 may be disposed. The first hole 160 may expose a portion of the upper surface of the pad capping portion 149p. The first hole 160 may be formed through a dry etching process. The lithium fluoride (LiF) constituting the pad capping portion 149p has excellent corrosion resistance to dry etching sources. Accordingly, the pad capping portion 149p may serve as an etch stop layer in the dry etching process.

Referring to FIG. 11, a second hole 161 exposing a portion of the surface of the fourth pad pattern 147p may be formed by etching the portion exposed by the first hole 160. The second hole 161 may be formed by etching the exposed surface of the pad capping portion 149p. A pad hole 310 may be configured to include the first hole 160 and the second hole 161.

The lithium fluoride (LiF) constituting the pad capping portion 149p reacts with a wet etching solution such as hydrofluoric acid (HF) or buffered oxide etchant (BOE) solution, allowing the process to proceed via wet etching. The silver (Ag)-magnesium (Mg) alloy (Ag:Mg) constituting the fourth pad pattern 147p has excellent chemical resistance to fluorine in the wet etching solution. Accordingly, the fourth pad pattern 147p may serve as an etch stop layer in the wet etching process.

In one example, the end of the pad capping portion 149p may have an undercut structure recessed inward by a predetermined depth d1 compared to the ends of the insulating layers of the pad insulating structure 305, but is not limited thereto.

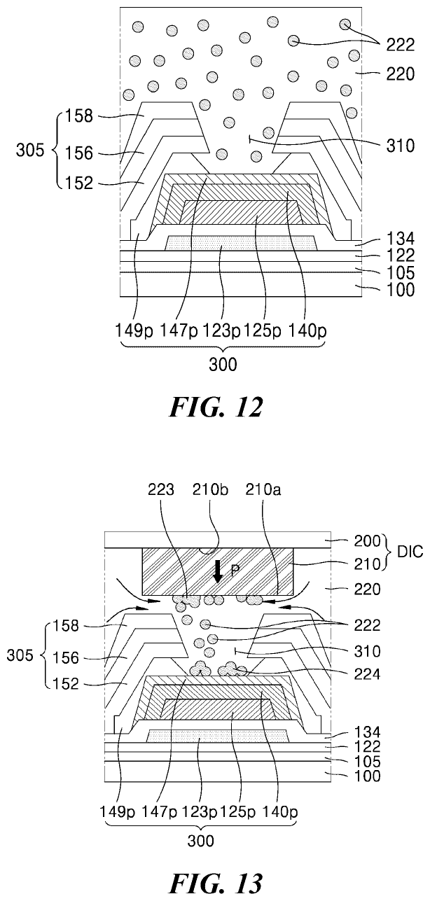

Referring to FIG. 12, a non-conductive filler 220 in which a plurality of solder particles 222 are dispersed may be applied on the substrate 100. The non-conductive filler 220 with the plurality of solder particles 222 dispersed therein may be applied over a space including the pad hole 310.

The plurality of solder particles 222 may include at least one of tin (Sn), indium (In), and bismuth (Bi). The non-conductive filler 220 may include an organic insulating material.

Referring to FIG. 13, a driver circuit chip package DIC is disposed on the substrate 100. The driver circuit chip package DIC may include a driver circuit chip 200 and a plurality of chip pads 210. One surface 210a of the chip pad 210 may face the substrate 100, and the other surface 210b may be in contact with the driver circuit chip 200. The chip pad 210 may include copper (Cu).

The driver circuit chip package DIC may be pressed in the direction P toward the substrate 100 at a first pressure while being heated to a first temperature. For example, it may be pressed at a first pressure range of 2 MPa to 6 MPa at a relatively low first temperature not exceeding 200 degrees. When pressed at the first pressure range at the relatively low first temperature, the solder particles 222 dispersed in the non-conductive filler 220 may melt. The melted solder particles 222 at the relatively low temperature may exhibit increased wettability.

The melted solder particles 222, previously dispersed in the non-conductive filler 220, move toward the pad hole 310, as indicated by the arrows. Due to the high reaction energy of the tin-copper (Sn—Cu) metal bond, the fluidity of the melted solder particles 222 toward the chip pad 210, which includes copper (Cu), may increase. A first intermetallic compound film 223 may be formed on the surface 210a of the chip pad 210 by the tin-copper (Sn—Cu) metal bond with the melted solder particles 222.

Some of the melted solder particles 222 that have moved toward the pad hole 310 may combine with the fourth pad pattern 147p to form a second intermetallic compound film 224. For example, the fourth pad pattern 147p may include a metal material with excellent solderability. For example, the fourth pad pattern 147p may include an alloy in which silver (Ag) and magnesium (Mg) are added in a ratio of 12:1.

The melted solder particles, having formed the first intermetallic compound film 223 and the second intermetallic compound film 224 on the surfaces of the chip pad 210 and the fourth pad pattern 147p of the bonding pad 300, respectively, may self-assemble and grow into crystals.

The phenomenon of the solder particles 222 melting, self-assembling, and growing may follow the Ostwald ripening principle, which is proportional to surface tension and solubility. For example, the Ostwald ripening principle is the principle by which particles dissolved in a solid solution or liquid sol grow into crystals. When the sizes of the dissolved particles vary, relatively larger particles are energetically more stable than relatively smaller particles. As a result, relatively smaller particles continue to dissolve and shrink, becoming adsorbed onto the surface of larger particles, allowing the larger particles to grow progressively until the smaller particles eventually disappear.

The solder particles may grow from the first intermetallic compound film 223 formed on the surface of the chip pad 210 toward the direction in which the bonding pad 300 is disposed. Additionally, the solder particles may grow from the second intermetallic compound film 224 formed on the surface of the fourth pad pattern 147p of the bonding pad 300 toward the direction in which the chip pad 210 is disposed.

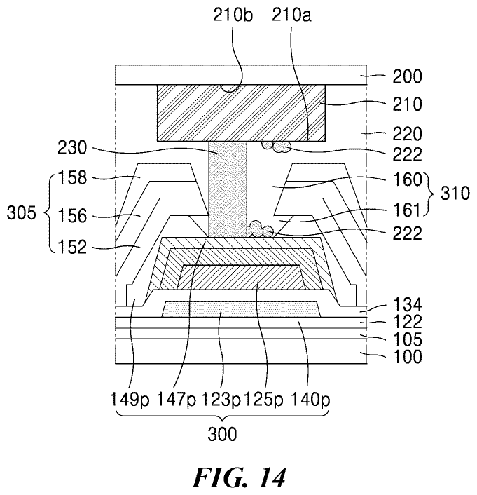

Accordingly, as shown in FIG. 14, the melted solder particles 222, previously dispersed in the non-conductive filler 220, may be implemented as a conductive structure 230 that mechanically and electrically connects the chip pad 210 and the bonding pad 300 through aggregation and growth.

In another embodiment, the conductive structure 230 may completely fill the pad hole 310, including the first hole 160 and the second hole 161. For example, the conductive structure 230 may completely fill the second hole 161 formed by the undercut structure of the pad capping portion 149p. As a result, the conductive structure 230 may stably maintain the mechanical connection between the bonding pad 300 and the chip pad 210 due to an anchor effect resulting from its shape fitting into the second hole 161 of the pad hole 310.

According to an embodiment of this specification, the conductive structure 230, composed of a self-assembling material, may mechanically and electrically connect the chip pad 210 and the bonding pad 300 in a stable manner. As a result, the conductive balls can be omitted, thereby preventing crack defects, short-circuit defects, or open-circuit defects caused by conductive balls. The mechanical and electrical connections between the chip pad 210 and the bonding pad 300 can be stably implemented, reducing the defect rate of the display apparatus. Therefore, the production energy required for manufacturing the display apparatus can be reduced, and greenhouse gas emissions can be lowered.

Additionally, since the chip pad 210 and the bonding pad 300 can be electrically connected without conductive balls, the design margin required for applying conductive balls can be secured. As a result, highly integrated pads can be designed in the chip pad area where the bonding pad 300 is disposed.

Furthermore, the bonding process between the driver circuit chip package and the substrate can be performed at a relatively lower temperature and pressure compared to using conductive balls. As a result, high-temperature reliability can be improved, making it applicable to products vulnerable to high-temperature and high-pressure processes. Consequently, the range of product fields that can be applied without conductive balls can be expanded.

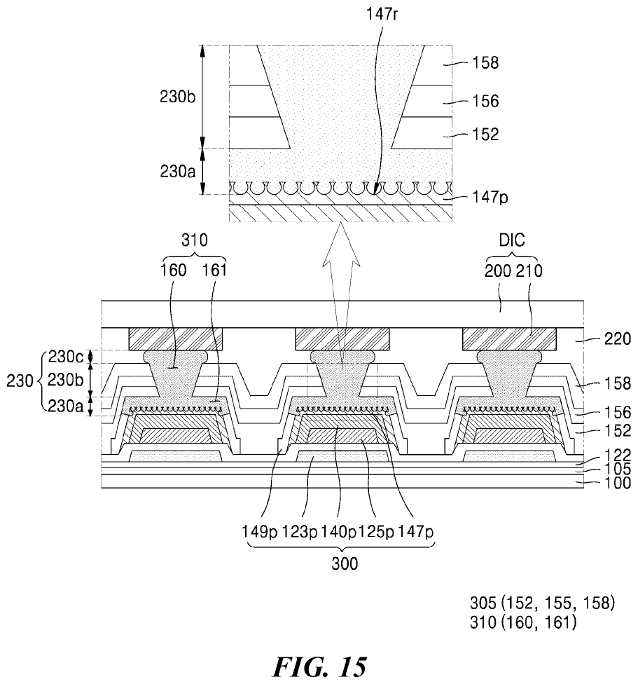

FIG. 15 is a diagram illustrating a pad portion according to another embodiment of this specification. In FIG. 15, the same reference numerals as those in FIGS. 3 and 4 denote the same components, and thus, redundant descriptions will be omitted or provided briefly.

Referring to FIG. 15, a pad portion according to another embodiment of this specification differs in the shape and position of the conductive structure 230.

A plurality of bonding pads 300 may be disposed on the substrate 100. A driver circuit chip package DIC may be disposed at a position facing the substrate 100. The driver circuit chip package DIC may include a driver circuit chip 200 and a plurality of chip pads 210. The driver circuit chip package DIC and the substrate 100 may be electrically connected through conductive structures 230 respectively disposed between the plurality of chip pads 210 and the plurality of bonding pads 300.

One bonding pad 300 may include a first pad pattern 123p, a second pad pattern 125p, a third pad pattern 140p, a fourth pad pattern 147p, and a pad capping part 149p. The first pad pattern 123p and the second pad pattern 125p may be disposed spaced apart from each other with a third interlayer insulating layer 134 interposed therebetween. The second pad pattern 125p may have its upper surface and side surfaces covered by the third pad pattern 140p.

A fourth pad pattern 147p may be disposed on the upper and side surfaces of the third pad pattern 140p. The fourth pad pattern 147p may include a plurality of recessed grooves 147r. A plurality of recessed grooves 147r may be disposed on the upper surface and a portion of the side surface of the fourth pad pattern 147p. The plurality of recessed grooves 147r may include a shape with consecutive concave grooves. The pad capping portion 149p may be disposed to surround the side surfaces of the fourth pad pattern 147p.

The bonding pad 300 may be covered by a pad insulating structure 305 including multiple insulating layers. The pad insulating structure 305 may include a first encapsulation layer 152, a third encapsulation layer 156, and a touch insulating layer 158. The pad insulating structure 305 may include a pad hole 310.

The pad hole 310 may include a first hole 160 and a second hole 161. The first hole 160 may penetrate the multilayer pad insulating structure 305 in a vertical direction with respect to an upper surface of the substrate 100. The second hole 161 may extend in a horizontal direction parallel to the upper surface of the substrate 100 from the lower part of the first hole 160. For example, the second hole 161 may extend toward the lower surface of the first encapsulation layer 152.

A conductive structure 230 may be disposed between the chip pad 210 and the bonding pad 300. One surface of the conductive structure 230 may be connected to the chip pad 210, and the other surface may be connected to the fourth pad pattern 147p of the bonding pad 300 exposed by the pad hole 310.

The conductive structure 230 may fill the first hole 160 and the second hole 161 of the pad hole 310. The conductive structure 230 may include a first portion 230a, a second portion 230b, and a third portion 230c. The first portion 230a of the conductive structure 230 may fill the second hole 161 of the pad hole 310 while contacting the surface of the plurality of recessed grooves 147r. As a result, the contact area between the conductive structure 230 and the fourth pad pattern 147p may increase. As the contact area between the conductive structure 230 and the fourth pad pattern 147p increases, contact resistance can be reduced, preventing electrical loss.

Additionally, the anchor effect resulting from the shape of the fourth pad pattern 147p fitting into each of the plurality of recessed grooves 147r can stably maintain the mechanical connection between the conductive structure 230 and the fourth pad pattern 147p of the bonding pad 300.

The second portion 230b of the conductive structure 230 may fill the first hole 160 of the pad hole 310. The third portion 230c of the conductive structure 230 may protrude from the first hole 160 of the pad hole 310 to connect with the chip pad 210. The first portion 230a, the second portion 230b, and the third portion 230c of the conductive structure 230 may form an integral structure.

The conductive structure 230 may be an alloy including at least one of tin (Sn), indium (In), and bismuth (Bi).

A non-conductive filler 220 may be disposed between the substrate 100 and the driver circuit chip 200. The non-conductive filler 220 may include an organic insulating material. For example, the organic insulating material may include an epoxy-based resin, but is not limited thereto.

According to another embodiment of this specification, the substrate 100 and the driver circuit chip 200 can be mechanically and electrically connected in a stable manner by the conductive structure 230.

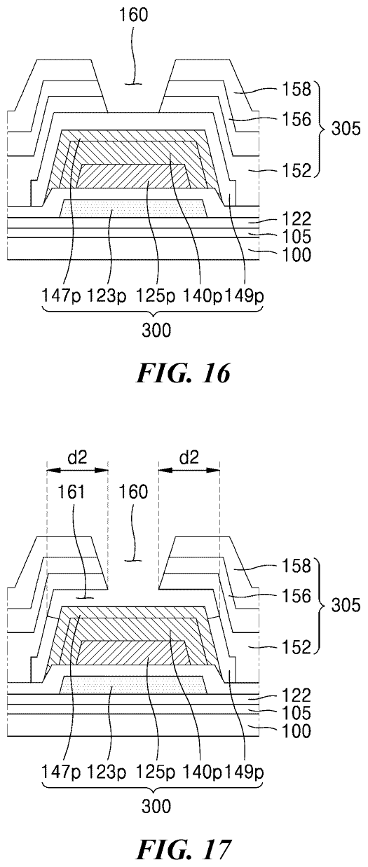

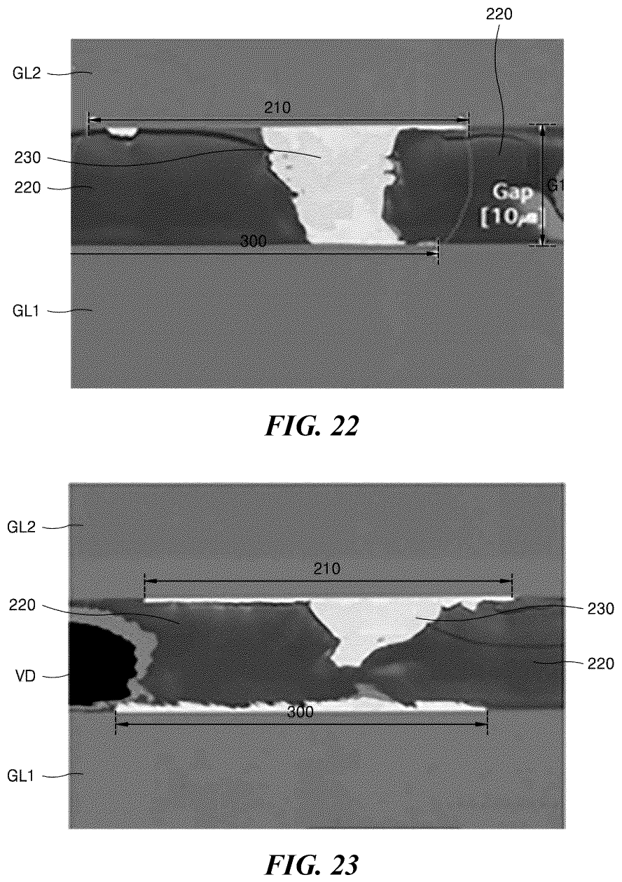

FIGS. 16 to 21 are diagrams illustrating a method of manufacturing a pad portion according to another embodiment of this specification. FIGS. 22 and 23 are diagrams illustrating the filling state of a conductive structure. FIGS. 16 to 21 include the same configuration as FIGS. 3 and 4, so redundant descriptions will be omitted or briefly explained. The same reference numerals may denote the same components.

Referring to FIG. 16, a bonding pad 300 may be disposed on the substrate 100. A buffer layer 105 and a first gate insulating layer 122 may be disposed between the substrate 100 and the bonding pad 300. One bonding pad 300 may include a first pad pattern 123p, a second pad pattern 125p, a third pad pattern 140p, a fourth pad pattern 147p, and a pad capping portion 149p. A pad insulating structure 305 having a first hole 160 of a pad hole 360 may be disposed on the bonding pad 300. The first hole 160 of the pad hole may be formed by a dry etching process using the pad capping portion 149p as an etch stop layer. A photoresist film may be disposed as an etching mask to prevent the pad insulating structure 305 from being etched.

Referring to FIG. 17, the exposed surface of the pad capping portion 149p may be etched to expose a portion of the surface of the fourth pad pattern 147p. The pad capping portion 149p may be etched through a wet etching process. The pad capping portion 149p may be over-etched inward by a predetermined depth d2 from the end of the pad insulating structure 305. For example, the pad capping portion 149p may be exposed up to a portion of the inclined surface of the side of the fourth pad pattern 147p. Accordingly, the pad hole 310 may include the first hole 160 and the second hole 161.

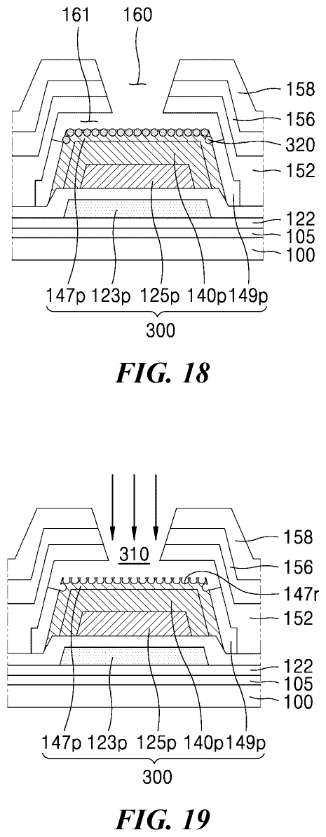

Referring to FIG. 18, a plurality of metal oxide particles 320 may be formed on the surface of the fourth pad pattern 147p. The fourth pad pattern 147p may be formed of the same material in the same process as the second electrode 147 in the display area AA. For example, the fourth pad pattern 147p may be formed of a metal alloy material such as a silver (Ag)-magnesium (Mg) alloy (Ag:Mg). As a result, magnesium (Mg) on the surface of the fourth pad pattern 147p may react with moisture or oxygen to generate metal oxide. The plurality of metal oxide particles 320 may be formed on the fourth pad pattern 147p by performing wet cleaning to supply moisture (H2O) or through natural oxidation when exposed to the atmosphere. The plurality of metal oxide particles 320 may include magnesium oxide (MgO). In one embodiment, the plurality of metal oxide particles 320 may be formed in a spherical shape.

Referring to FIG. 19, a reprocessing step may be performed on the surface of the fourth pad pattern 147p. The reprocessing step may be conducted by supplying a hydrofluoric acid (HF) solution onto the pad hole 310. By removing the plurality of metal oxide particles 320 (see FIG. 18) formed on the fourth pad pattern 147p through the reprocessing step, a plurality of recessed grooves 147r may be formed. The plurality of recessed grooves 147r may be implemented as a shape with consecutive concave grooves. For example, the concave grooves may have a hemispherical shape. As a result, the surface roughness of the fourth pad pattern 147p, where the plurality of recessed grooves 147r are disposed, may increase. For example, a portion of the upper surface and side surfaces of the fourth pad pattern 147p may include an uneven shape.

By removing the plurality of metal oxide particles 320 containing magnesium oxide (MgO), the proportion of silver (Ag) in the material constituting the fourth pad pattern 147p may increase. For example, the fourth pad pattern 147p may be composed of an alloy in which silver (Ag) and magnesium (Mg) are added in a ratio of 12:1.

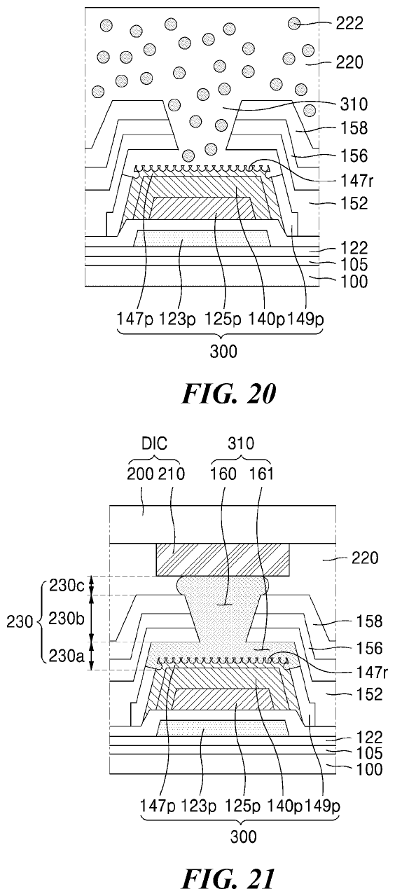

Referring to FIG. 20, a non-conductive filler 220 in which a plurality of solder particles 222 are dispersed may be applied. The non-conductive filler 220 with the plurality of solder particles 222 dispersed therein may be applied over a space including the pad hole 310. The plurality of solder particles 222 may include at least one of tin (Sn), indium (In), and bismuth (Bi). The non-conductive filler 220 may include an organic insulating material.

Referring to FIGS. 21 and 22, a driver circuit chip package DIC is disposed on the substrate 100. The driver circuit chip package DIC may include a driver circuit chip 200 and a plurality of chip pads 210.

The driver circuit chip package DIC may be heated to a first temperature in the direction of the substrate 100 while being pressed with a first pressure. For example, the first temperature may be below 200° C., and the first pressure may range from 2 MPa to 6 MPa. According to an embodiment of this specification, the process can be performed at a relatively lower temperature and pressure compared to using conductive balls. As a result, high-temperature reliability can be improved, making it applicable to products vulnerable to high-temperature and high-pressure conditions. Therefore, the range of products that can adopt the method of bonding the driver circuit chip package DIC and the substrate 100 using the conductive structure 230 without conductive balls can be diversified.

When pressure is applied while increasing the temperature, some of the plurality of solder particles 222 dispersed in the non-conductive filler 220 may form an intermetallic compound film at the interface of the chip pad 210 and grow toward the substrate 100, while others may form an intermetallic compound film on the surface of the fourth pad pattern 147p of the bonding pad 300 and grow toward the driver circuit chip 200.

The plurality of solder particles 222 grown between the chip pad 210 and the bonding pad 300 may fill both the first hole 160 and the second hole 161 of the pad hole 310, growing to form a conductive structure 230. According to another embodiment of this specification, by removing the plurality of metal oxide particles 320, the concentration of silver (Ag) in the material constituting the fourth pad pattern 147p increases, facilitating the formation of an intermetallic compound film with the solder particles 222. As a result, the aggregation yield of the solder particles 222 can be improved.

The conductive structure 230 may include a first portion 230a filling the second hole 161 of the pad hole 310, a second portion 230b filling the first hole 160, and a third portion 230c protruding from the first hole 160 and contacting the chip pad 210.

As the first portion 230a of the conductive structure 230 is formed while filling the recessed grooves 147r of the fourth pad pattern 147p, the surface area may increase. As a result, contact resistance can be improved. Additionally, as the first portion 230a of the conductive structure 230 is formed while filling the recessed grooves 147r, adhesion can be enhanced.

Referring to FIGS. 22 and 23, the filling rate of the conductive structure 230 may vary depending on the height of the gap G1 between the opposing substrates GL1 and GL2. For example, the height of the gap G1 between the bonding pad 300 on the first substrate GL1 and the chip pad 210 on the second substrate GL2 may be equal to or less than 10 micrometers In this case, the self-assembly property, where the solder particles dispersed in the non-conductive filler 220 aggregate and grow into crystals, is excellent, allowing the conductive structure 230 to grow normally between the bonding pad 300 and the chip pad 210 (see FIG. 22).

In contrast, when the gap between the bonding pad 300 on the first substrate GL1 and the chip pad 210 on the second substrate GL2 widens, the height of the gap G2 may exceed 10 micrometers. When the height of the gap G2 exceeds 10 micrometers, as shown in FIG. 23, the conductive structure 230 may not grow sufficiently within the gap G2, resulting in the non-conductive filler 220 being disposed between the bonding pad 300 and the conductive structure 230. Additionally, voids VD may occur within the non-conductive filler 220. Therefore, it is preferable that the height of the gap G1 between the bonding pad 300 and the chip pad 210 on the second substrate GL2 is equal to or less than 10 micrometers.

The display apparatus according to various embodiments of this specification may be described as follows.

A display apparatus according to an embodiment of this specification may include a substrate including a display area and a non-display area outside the display area, a plurality of light-emitting elements arranged in the display area, a plurality of bonding pads arranged in the non-display area of the substrate, a pad insulating structure disposed on the plurality of bonding pads, a pad hole penetrating the pad insulating structure to expose a portion of the surface of the plurality of bonding pads, a driver circuit chip with a plurality of chip pads arranged spaced apart from the bonding pads, and a plurality of conductive structures disposed between the bonding pads and the chip pads, wherein the conductive structures may connect to the bonding pads through the pad hole.

According to some embodiments of this specification, the space between the bonding pads, the chip pads, and the plurality of conductive structures may be filled with a non-conductive filler.

According to some embodiments of this specification, the light-emitting element may include a first electrode, a light-emitting layer on the first electrode, and a second electrode on the light-emitting layer.

According to some embodiments of this specification, the second electrode may include an alloy of silver (Ag) and magnesium (Mg), with the proportion of silver (Ag) being higher than that of magnesium (Mg) in the total alloy.

According to some embodiments of this specification, the bonding pad may include the same material as the second electrode.

According to some embodiments of this specification, the conductive structure may include an alloy including at least one of tin (Sn), indium (In), and bismuth (Bi).

According to some embodiments of this specification, the bonding pad may include a first pad pattern disposed on the substrate, a second pad pattern disposed spaced apart from the first pad pattern, a third pad pattern on the second pad pattern, a fourth pad pattern on the third pad pattern, and a pad capping portion exposing a portion of the surface of the fourth pad pattern.

According to some embodiments of this specification, the fourth pad pattern may include the same material as the second electrode.

According to some embodiments of this specification, the pad capping portion may include a material having higher resistance to a dry etching source than the pad insulating structure.

According to some embodiments of this specification, the pad hole may include a first hole penetrating the pad insulating structure in a direction perpendicular to an upper surface of the substrate; and a second hole extending in a horizontal direction parallel with the upper surface of the substrate from the lower part of the first hole.

According to some embodiments of this specification, the fourth pad pattern may include a flat upper surface.

According to some embodiments of this specification, the fourth pad pattern may include a plurality of recessed grooves formed with a concave shape consecutively on the upper surface, and the recessed grooves may have a hemispherical shape.

According to some embodiments of this specification, the fourth pad pattern may include an alloy of silver (Ag) and magnesium (Mg), with the proportion of silver (Ag) being higher than that of magnesium (Mg) in the total alloy.

According to some embodiments of this specification, the pad hole may include a first hole penetrating the pad insulating structure in a direction perpendicular to an upper surface of the substrate, and a second hole extending in a horizontal direction parallel with the upper surface of the substrate from the lower part of the first hole to expose the recessed grooves of the fourth pad pattern.

According to some embodiments of this specification, the conductive structure may include a first portion filling the second hole of the pad hole; a second portion filling the first hole on the first portion; and a third portion protruding from the first hole and connected to the chip pad.

A display apparatus according to another embodiment of this specification may include a substrate including a display area and a non-display area outside the display area, a plurality of bonding pads arranged in the non-display area of the substrate, a pad insulating structure disposed on the plurality of bonding pads, a pad hole penetrating the pad insulating structure to expose a portion of the surface of the plurality of bonding pads, a driver circuit chip with a plurality of chip pads arranged spaced apart from the bonding pads, and a plurality of conductive structures disposed between the bonding pads and the chip pads, wherein a plurality of recessed grooves are disposed on the upper surface of the bonding pad, and the conductive structure may fill the plurality of recessed grooves of the bonding pad through the pad hole.

According to the embodiments of this specification, a conductive structure using a self-assembling material can electrically and mechanically connect the bonding pad of the display panel and the chip pad of the driver circuit chip. As a result, the conductive balls can be omitted, thereby preventing crack defects, short-circuit defects, or open-circuit defects caused by conductive balls.

Therefore, the mechanical and electrical connections between the display panel and the driver circuit chip can be stably implemented, reducing the defect rate of the display apparatus. This leads to the effect of reducing the production energy required for manufacturing the display apparatus and lowering greenhouse gas emissions.

Additionally, since the driver circuit chip and the display panel can be electrically connected without conductive balls, the design margin required for applying conductive balls can be secured, allowing for the design of highly integrated pads in the pad area.

Moreover, by improving adhesion between the bonding pad of the display panel and the self-assembling material of the conductive structure, high-temperature reliability can be enhanced, making it applicable to products vulnerable to high-temperature and high-pressure processes. Consequently, the range of products that can be applied without conductive balls can be diversified.

The advantageous effects of this specification are not limited to the foregoing, and other effects not mentioned will be clearly understood by those skilled in the art from the detailed description.

Although embodiments of this specification have been described in detail with reference to the accompanying drawings, it should be noted that the specification is not necessarily limited to these embodiments and can be modified in various ways without departing from the scope of the technical concept of the disclosure. Therefore, the embodiments disclosed in this specification are not intended to limit but to describe the technical idea of the specification, and the scope of the technical idea of the specification is not limited by the embodiments. Therefore, it should be understood that the embodiments described above are exemplary and not limited in all aspects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a display area and a non-display area adjacent to the display area;
a plurality of light-emitting elements in the display area;
a plurality of bonding pads in the non-display area of the substrate;
a pad insulating structure on the plurality of bonding pads;
a pad hole penetrating the pad insulating structure to expose a portion of a surface of the plurality of bonding pads;
a driver circuit chip with a plurality of chip pads spaced apart from the bonding pads; and
a plurality of conductive structures between the bonding pads and the chip pads,
wherein the conductive structures are connected to the bonding pads through the pad hole.

2. The display apparatus of claim 1, further comprising: a non-conductive filler,
wherein the non-conductive filler is present in a space between the bonding pads, the chip pads, and the plurality of conductive structures.

3. The display apparatus of claim 1, wherein the light-emitting element comprises:
a first electrode;
a light-emitting layer on the first electrode; and
a second electrode on the light-emitting layer.

4. The display apparatus of claim 3, wherein the second electrode comprises an alloy of silver and magnesium, with the proportion of silver being higher than that of magnesium in the total alloy.

5. The display apparatus of claim 4, wherein the bonding pad comprises a same material as the second electrode.

6. The display apparatus of claim 4, wherein the conductive structure comprises an alloy including at least one of tin, indium, and bismuth.

7. The display apparatus of claim 3, wherein the bonding pad comprises:
a first pad pattern on the substrate;
a second pad pattern spaced apart from the first pad pattern;
a third pad pattern on the second pad pattern;
a fourth pad pattern on the third pad pattern; and
a pad capping portion exposing a portion of the surface of the fourth pad pattern.

8. The display apparatus of claim 7, wherein the fourth pad pattern comprises a same material as the second electrode.

9. The display apparatus of claim 7, wherein the pad capping portion comprises a material having higher resistance to a dry etching source than the pad insulating structure.

10. The display apparatus of claim 1, wherein the pad hole comprises:
a first hole penetrating the pad insulating structure in a direction perpendicular to an upper surface of the substrate; and
a second hole extending in a horizontal direction parallel with the upper surface of the substrate from the lower part of the first hole.

11. The display apparatus of claim 7, wherein the fourth pad pattern comprises a flat upper surface.

12. The display apparatus of claim 7, wherein the fourth pad pattern comprises a plurality of recessed grooves formed with a concave shape consecutively on the upper surface.

13. The display apparatus of claim 12, wherein the recessed grooves have a hemispherical shape.

14. The display apparatus of claim 12, wherein the fourth pad pattern comprises an alloy of silver and magnesium, with the proportion of silver being higher than that of magnesium in the total alloy.

15. The display apparatus of claim 12, wherein the pad hole comprises:
a first hole penetrating the pad insulating structure in a direction perpendicular to an upper surface of the substrate; and
a second hole extending in a horizontal direction parallel with the upper surface of the substrate from the lower part of the first hole to expose the recessed grooves of the fourth pad pattern.

16. The display apparatus of claim 15, wherein the conductive structure comprises:
a first portion filling the second hole of the pad hole;
a second portion filling the first hole on the first portion; and
a third portion protruding from the first hole and connected to the chip pad.

17. A display apparatus comprising:
a substrate including a display area and a non-display area adjacent to the display area;
a plurality of bonding pads in the non-display area of the substrate;
a pad insulating structure on the plurality of bonding pads;
a pad hole penetrating the pad insulating structure to expose a portion of the surface of the plurality of bonding pads;
a driver circuit chip with a plurality of chip pads spaced apart from the bonding pads; and
a plurality of conductive structures between the bonding pads and the chip pads,
wherein a plurality of recessed grooves is on the upper surface of the bonding pad, and the conductive structure fills the plurality of recessed grooves of the bonding pad through the pad hole.

18. The display apparatus of claim 17, wherein the bonding pad comprises:
a first pad pattern on the substrate;
a second pad pattern spaced apart from the first pad pattern;
a third pad pattern on the second pad pattern;
a fourth pad pattern on the third pad pattern with the plurality of recessed grooves disposed at least on the upper surface; and
a pad capping portion exposing a portion of the surface of the fourth pad pattern.

19. The display apparatus of claim 18, wherein the fourth pad pattern comprises an alloy of silver and magnesium, with the proportion of silver being higher than that of magnesium in the total alloy.

20. The display apparatus of claim 18, wherein the pad hole comprises:
a first hole penetrating the pad insulating structure in a direction perpendicular to an upper surface of the substrate; and
a second hole extending in a horizontal direction parallel with the upper surface of the substrate from the lower part of the first hole to expose the recessed grooves of the fourth pad pattern.
